(19) United States
(12) Patent Application Publication
(10) Pub. No.: US 2012/0146041 A1
(43) Pub. Date: Jun. 14, 2012

(54) ORGANIC LIGHT EMITTING DISPLAY APPARATUS AND METHOD OF MANUFACTURING THE SAME

(75) Inventors: Byung-Uk Han, Yongin-City (KR); Sung-Soo Koh, Yongin-City (KR); Jung-Jun Im, Yongin-City (KR)

(73) Assignee: SAMSUNG MOBILE DISPLAY CO., LTD., Yongin-City (KR)

(21) Appl. No.: 13/244,148

(22) Filed: Sep. 23, 2011

(30) Foreign Application Priority Data
Dec. 14, 2010 (KR) 10-2010-0127862

(51) Int. Cl. H01L 33/08; H01L 21/336

(52) U.S. Cl. 257/72; 438/158; 257/40; 438/99; 257/E33.053; 257/E21.412

(57) ABSTRACT

An organic light emitting display apparatus includes a first substrate including a display region disposed in a center of one surface thereof and a bonding region formed along a closed loop to surround the display region; a semiconductor layer corresponding to the bonding region of the first substrate, formed along the closed loop to surround the display region, and comprising a polycrystal; at least one insulation layer formed over the semiconductor layer; a bonding member formed over the at least one insulation layer and formed in a region corresponding to the semiconductor layer; and a second substrate having the one surface disposed to face one surface of the first substrate and coupled to the bonding member to encapsulate the display region of the first substrate.

### CROSS-REFERENCE TO RELATED PATENT APPLICATION

This application claims the benefit of Korean Patent Application No. 10-2010-0127862, filed on Dec. 14, 2010, in the Korean Intellectual Property Office, the disclosure of which is incorporated herein in its entirety by reference.

### BACKGROUND

1. Field

The present disclosure relates to an organic light emitting display apparatus and a method of manufacturing the organic light emitting display apparatus, and more particularly to, an organic light emitting display apparatus that is encapsulated by applying a light source.

2. Description of the Related Art

Organic light emitting diodes (OLEDs) emit light by injecting charges into organic films formed between cathodes for injecting electrons and anodes for injecting holes, pairing the electrons and the holes, and annihilating the paired electrons and holes. OLEDs enable formation of a device on a flexible transparent substrate, such as plastic, operate at a voltage (less than about 10V) lower than plasma display panels or inorganic EL displays, consume less power, and have excellent color effect.

An organic light emitting display apparatus comprises OLEDs, a lower substrate in which various types of electronic devices for operating OLEDs are formed, and an encapsulation substrate that are disposed to face lower substrates for encapsulation. The lower and encapsulation substrates are adhered to each other by using a bonding member. However, if the bonding is not sufficient, external moisture or oxygen would penetrate into OLEDs through an interface between the lower substrate and the bonding member or through an interface between the encapsulation substrate and the bonding member. This may reduce the lifetime of the organic light emitting display apparatus.

### SUMMARY

An aspect of the present invention provides an organic light emitting display apparatus including a semiconductor layer formed in a bonding area of a lower substrate, and a method of manufacturing the organic light emitting display apparatus.

Another aspect of the present invention provides an organic light emitting display apparatus including a concave portion formed in a bonding area of a lower substrate, and a method of manufacturing the organic light emitting display apparatus.

According to an aspect of the present invention, there is provided an organic light emitting display apparatus including: a first substrate including a display region disposed in a center of one surface thereof and a bonding region formed along a closed loop to surround the display region; a semiconductor layer corresponding to the bonding region of the first substrate, formed along the closed loop to surround the display region, and including a polycrystal; at least one insulation layer formed on the semiconductor layer; a bonding member formed on the at least one insulation layer and formed in a region corresponding to the semiconductor layer; and a second substrate having one surface disposed to face the surface of the first substrate and coupled to the bonding member to encapsulate the display region of the first substrate.

The semiconductor layer may include polycrystalline polysilicon.

The semiconductor layer may include polycrystalline polysilicon doped with impurities.

The apparatus may further include: a thin film transistor (TFT) including: an active layer formed in the display region of the first substrate; a gate insulation layer formed on the active layer; a gate electrode formed on the gate insulation layer and insulated from the active layer; an interlayer insulation layer formed on the gate electrode; and source and drain electrodes formed on the interlayer insulation layer and contacting the active layer.

The active layer may be formed simultaneously with formation of the semiconductor layer on a same layer as a layer on which the semiconductor layer is formed.

The insulation layer may include the gate insulation layer and the interlayer insulation layer.

The insulation layer may include the gate insulation layer and the interlayer insulation layer, and wherein a concave portion may be formed in a region of the interlayer insulation layer corresponding to the bonding region, and a portion of the bonding member is received in the concave portion and contacts the gate insulation layer.

The insulation layer may include the gate insulation layer and the interlayer insulation layer, and wherein a concave portion may be formed in the interlayer insulation layer and the gate insulation layer at a region which corresponds to the bonding region, and a portion the bonding member is buried in the concave portion and contacts the semiconductor layer.

The insulation layer may include the gate insulation layer and the interlayer insulation layer, and wherein a concave portion may be formed in the interlayer insulation layer, the gate insulation layer, and the semiconductor layer at a region which corresponds to the bonding region, and the bonding member is received in the concave portion.

A width of the concave portion may be smaller than that of the bonding member.

The apparatus may further include: a buffer layer formed on the entire portion of the surface of the first substrate.

According to another aspect of the present invention, there is provided a method of manufacturing an organic light emitting display apparatus, the method including: providing a first substrate including a display region disposed in a center of one surface thereof and a bonding region formed along a closed loop to surround the display region; forming a semiconductor layer corresponding to the bonding region of the first substrate, wherein the semiconductor layer is formed along the closed loop to surround the display region, and including a polycrystal; forming at least one insulation layer on the semiconductor layer; forming a bonding member on the at least one insulation layer and formed in a region corresponding to the semiconductor layer; and disposing a second substrate having one surface to face the surface of the first substrate; and applying laser to a region corresponding to the bonding region through the second substrate, thereby melting the bonding member, and encapsulating the display region.

The semiconductor layer may include polycrystalline polysilicon, the method further including: doping the semiconductor layer with impurities.

The method may further include: forming an active layer in the display region of the first substrate; forming a gate insulation layer on the active layer; forming a gate electrode insulated from the active layer on the gate insulation layer; forming an interlayer insulation layer on the gate electrode; and forming source and drain electrodes on the interlayer insulation layer and contacting the active layer.

The semiconductor layer may be formed simultaneously with the formation of the active layer.

The insulation layer may include the gate insulation layer and the interlayer insulation layer.

The insulation layer may include the gate insulation layer and the interlayer insulation layer, the forgoing method may further include, before forming the bonding member, forming a concave portion in a region of the interlayer insulation layer corresponding to the bonding region, wherein the bonding member is received in the concave portion and contacts the gate insulation layer.

The insulation layer may include the gate insulation layer and the interlayer insulation layer, the method may further include, before forming the bonding member, forming a concave portion in the interlayer insulation layer and the gate insulation layer at a region which corresponds to the bonding region, wherein the bonding member is received in the concave portion and contacts the semiconductor layer.

The insulation layer may include the gate insulation layer and the interlayer insulation layer, the method may further include, before forming the bonding member, forming a concave portion is formed in the interlayer insulation layer, the gate insulation layer, and the semiconductor layer at a region which corresponds to the bonding region, wherein the bonding member is received in the concave portion.

The method may further include forming a buffer layer on the entire portion of the surface of the first substrate.

### BRIEF DESCRIPTION OF THE DRAWINGS

The above and other features and advantages of the present invention become more apparent by describing embodiments in detail with reference to the attached drawings in which:

FIG. 1 is a cross-sectional view of an organic light emitting display apparatus according to an embodiment of the present invention;

FIG. 2 is a plan view of the organic light emitting display apparatus taken along a line I-I′ of FIG. 1;

FIG. 3 is a cross-sectional view of a bonding region of FIG. 1 according to an embodiment of the present invention;

FIGS. 4 through 6 are cross-sectional views of a bonding region according to embodiments of the present invention; and

FIGS. 7 through 10 are diagrams for explaining a method of manufacturing the organic light emitting display apparatus of FIG. 1 according to embodiments of the present invention.

### DETAILED DESCRIPTION OF EMBODIMENTS

Hereinafter, embodiments of the present invention are described in detail with reference to the attached drawings.

As the invention allows for various changes and numerous embodiments, particular embodiments are illustrated in the drawings and described in detail in the written description. However, this is not intended to limit the present invention to particular modes of practice, and it is to be appreciated that all changes, equivalents, and substitutes that do not depart from the spirit and technical scope of the present invention are encompassed in the present invention. In the description, certain detailed explanations of related art are omitted when it is deemed that they may unnecessarily obscure the essence of the invention.

While such terms as “first,” “second,” etc., may be used to describe various components, such components must not be limited to the above terms. The above terms are used only to distinguish one component from another.

The terms used in the present specification are merely used to describe particular embodiments, and are not intended to limit the present invention. An expression used in the singular encompasses the expression of the plural, unless it has a clearly different meaning in the context. In the present specification, it is to be understood that the terms such as “including” or “having,” etc., are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

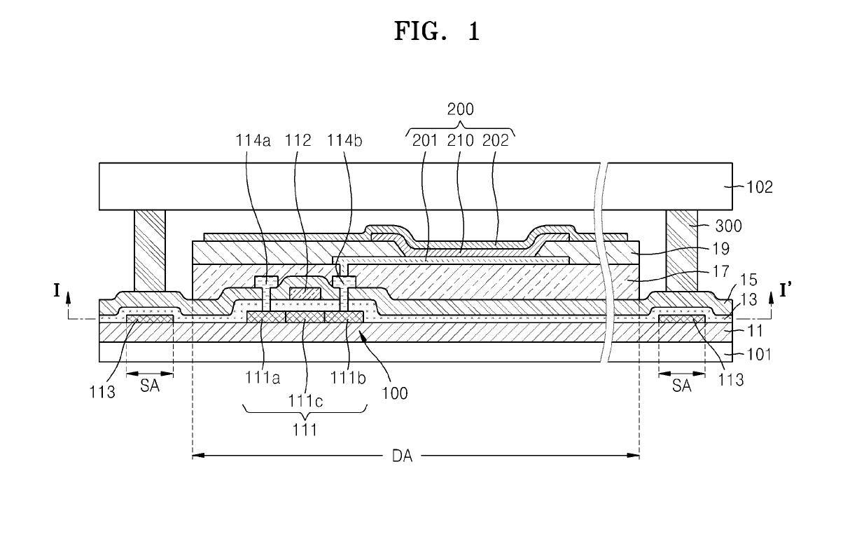

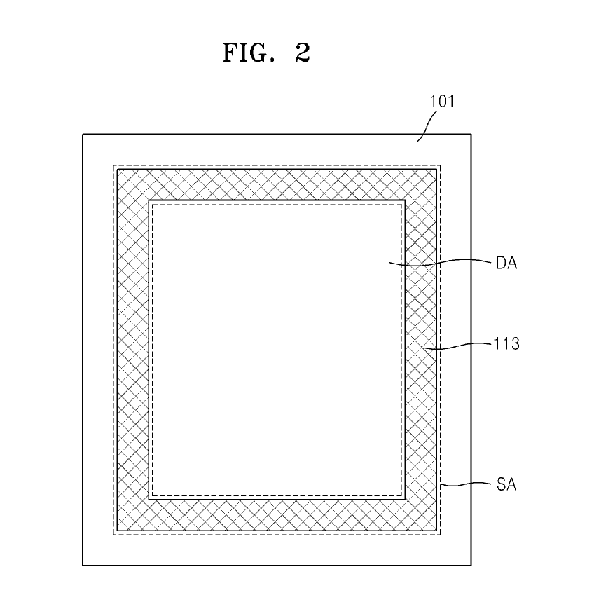

FIG. 1 is a cross-sectional view of an organic light emitting display apparatus according to an embodiment of the present invention. FIG. 2 is a plan view of the organic light emitting display apparatus taken along a line I-I′ of FIG. 1.

Referring to FIG. 1, the organic light emitting display apparatus comprises a lower substrate, an encapsulation substrate, and a bonding member 300 for bonding the lower substrate and the encapsulation substrate.

The lower substrate includes a first substrate 101 formed of glass, a semiconductor layer 113 formed on the first substrate 101, at least one insulation layer and various types of electronic devices including an organic light emitting device 200. An encapsulation substrate includes a second substrate 102 formed of glass. Although not shown, a barrier layer may be further formed on the second substrate 102 to prevent ion impurities from spreading therein and moisture or external air from penetrating thereinto.

The first substrate 101 is partitioned into a display region DA and a bonding region SA. Referring to FIG. 2, the display region DA is disposed in the center of the first substrate 101 and includes a plurality of pixels. Each pixel includes at least one electronic device, including the organic light emitting device 200 and a thin film transistor (TFT) 100 for operating the organic light emitting device 200. The bonding region SA is disposed on the first substrate 101 along a closed loop to surround the display region DA. The bonding member 300 is then disposed on the bonding region SA.

A buffer layer 11 is formed on the first substrate 101. The buffer layer 11 is entirely formed on the first substrate 101 to correspond to the bonding region SA and the display region DA. The buffer layer 11 prevents ion impurities from spreading in the first substrate 101, prevents moisture or external air from penetrating into the first substrate 101, and planarizes the surface of the first substrate 101. The buffer layer 11 may include at least one insulation layer. For example, the buffer layer 11 may be formed by alternately depositing a SiO₂ layer and a SiN_{X} layer.

An active layer 111 and a semiconductor layer 113 are formed on the buffer layer 11. Although terms are distinctively used, the active layer 111 and the semiconductor layer 113 are formed of the same material at the same stage. The active layer 111 is formed in the display region DA in which the TFT 100 is formed. The semiconductor layer 113 is formed in the bonding region SA. Referring to FIG. 2, in one embodiment, the semiconductor layer 113 is formed along the closed loop to surround the display region DA, like the bonding region SA.

The semiconductor layer 113 of the present embodiment reflects, diffracts, and scatters a laser beam that passes through the bonding member 300 and re-irradiates the laser beam to the bonding member 300 when the bonding member 300 is melted by the laser beam. Thus, an amount of heat applied to the bonding member 300 increases, thereby increasing an effective bonding area of the bonding member 300. In this regard, the effective bonding area means an area where the melted bonding member 300 is substantially coupled to the lower substrate or the second substrate 102. Thus, a bonding area between the lower substrate and the bonding member 300 increases, and mechanical strength improves. In particular, the semiconductor layer 113 is continuously disposed along the bonding region SA, so that the laser beam can be uniformly reflected, diffracted, and scattered in the entire portion of the bonding region SA.

The active layer 111 and the semiconductor layer 113 are formed of a semiconductor material. According to the present embodiment, in particular, the semiconductor layer 113 includes polycrystalline polysilicon having grains of sizes of several Å (Angstrom) and several hundred Å. Polysilicon (crystalline silicon) may be formed by crystallizing amorphous silicon. Amorphous silicon may be crystallized by using various methods, such as rapid thermal annealing (RTA), solid phase crystallization (SPC), excimer laser annealing (ELA), metal induced crystallization (MIC), metal induced lateral crystallization (MILC), sequential lateral solidification (SLS), etc.

Meanwhile, according to another embodiment, the semiconductor layer 113 may be doped with ion impurities by simultaneously doping a source region 111a and a drain region 11b of the active layer 111. Thus, the semiconductor layer 113 may include the polycrystalline polysilicon doped with impurities.

The semiconductor layer 113 of the present embodiment includes the polycrystalline polysilicon, which can more easily reflect, scatter, and diffract the laser beam on the surface of crystal. When an ellipsometer is used to irradiate a He/Ne laser at an angle of about 70 degrees, a real component of a reflective index of an element of polysilicon is about 4, which is greater than 3.7 of a real component of a reflective index of an element that is a metal, such as molybdenum. To form the semiconductor layer 113 in the bonding region SA and reflect, scatter, and diffract the laser beam involves less design limitations than to form a metal layer such as molybdenum in the bonding region SA and reflect, scatter, and diffract the laser beam. Although not shown, an electric device of the display region DA operates by receiving external power and a signal. A conductive wiring that transfers the power and signal is connected to the display region DA across the bonding region SA. Thus, to form a metal layer in the bonding region SA so as to reflect, scatter, and diffract the applied laser beam involves design limitations due to the conductive wiring that externally transfers the power and signal. Furthermore, static electricity, electromagnetic waves, and resistance between the metal layer formed in the bonding region SA and the conductive wiring may cause malfunctions. However, when the semiconductor layer 113 is formed in the bonding region SA and the laser beam is reflected, scattered, and diffracted according to the present embodiment, the laser beam may be re-irradiated to the bonding member 300 because of high reflection, scattering, and diffraction performances of the laser beam by the semiconductor layer 113. Thus, design limitations advantageously decrease.

In particular, when the semiconductor layer 113 is doped with impurities, an energy band gap of the semiconductor layer 113 may be adjusted by using impurities. Thus, absorption of the laser beam by the semiconductor layer 113 may be controlled. Furthermore, since impurities that are particles can serve as mediums of scattering and reflection, the reflection, scattering, and diffraction performances of the laser beam by the semiconductor layer 113 may increase.

Next, a gate insulation layer 13 is formed on the active layer 111 and the semiconductor layer 113. The gate insulation layer 13 is entirely formed over both the display region DA and the bonding region SA. The gate insulation layer 13 may be formed as an insulator, may have a structure of a single layer or multiple layers, and may be formed of organic materials, inorganic materials, or compounds of organic and inorganic materials. For example, the gate insulation layer 13 may be formed by alternately depositing a SiO₂ layer and a SiN_{X} layer.

Meanwhile, a gate electrode 112 is formed on the gate insulation layer 13 corresponding to the active layer 111 of the TFT 100 formed in the display region DA. An interlayer insulation layer 15 is formed on the gate electrode 112.

The interlayer insulation layer 15 is entirely formed over both the display region DA and the bonding region SA. The interlayer insulation layer 15 may be formed as an insulator, may have a structure of a single layer or multiple layers, and may be formed of organic materials, inorganic materials, or compounds of organic and inorganic materials. For example, the interlayer insulation layer 15 may be formed by alternately depositing a SiO₂ layer and a SiN_{X} layer.

Meanwhile, a source electrode 114a and a drain electrode 114b are formed on the interlayer insulation layer 15 of the TFT 100 in the display region DA, and contact the active layer 111 through the interlayer insulation layer 15 and the gate insulation layer 13.

The stacking structure of the TFT 100 is not limited thereto, and in other embodiments, the TFT 100 may have an alternative one selected from various TFT structures.

Meanwhile, a planarization layer 17 is formed on the source electrode and drain electrode 114a and 114b and the interlayer insulation layer 15 of the display region DA. The planarization layer 17 may be formed of one or more organic insulation materials selected from the group consisting of polyimide, polyamide, acrylic resin, benzocylcobutine, and phenolic resin. However, the present invention is not limited thereto and the planarization layer 17 may be formed of inorganic insulation materials.

A pixel electrode 201 is formed on the planarization layer 17 and is electrically connected to the source electrode 114a or the drain electrode 114b through a via hole. A pixel definition layer 19 is formed on the pixel electrode 201. A pixel opening portion is formed in the pixel definition layer 19 through which at least a part of the pixel electrode 201 is exposed. A light emitting member 210 is formed on the pixel electrode 210 exposed through the pixel opening portion.

The light emitting member 210 may use a low or high molecular organic layer. The light emitting member 210 may have a single or compound structure including a hole injection layer (HIL), a hole transport layer (HTL), an emission layer (EML), an electron transport layer (ETL), an electron injection layer (EIL), etc., and may be formed of various organic materials such as copper phthalocyanine (CuPc), N,N′-Di(naphthalene-1-yl)-N,N′-diphenyl-benzidine (NPB), (tris-8-hydroxyquinoline aluminum) (Alq3), etc.

A facing electrode 202 is formed on the light emitting member 210 to wholly cover the display region DA. The pixel electrode 201 and the facing electrode 202 are insulated from each other by the light emitting member 210 so that light is emitted by the light emitting member 210 by applying voltages having different polarities to the light emitting member 210.

Meanwhile, the bonding member 300 is formed in the bonding region SA corresponding to the semiconductor layer 113 formed on the interlayer insulation layer 15. Thus, the bonding member 300 is formed along a closed loop to surround the display region DA so that the organic light emitting device 200 and various electronic devices that are disposed in the display region DA can be encapsulated.

If a light source, like a laser beam, is applied to the bonding member 300 disposed in the bonding region SA, the bonding member 300 is melted and cured and bonds the lower substrate and the second substrate 102 to each other. In this regard, the bonding member 300 may be a glass frit. For example, the glass frit used as the bonding member 300 may be at least one selected from the group consisting of K2O, Sb2O3, ZnO, TiO2, Al2O3, WO3, SnO, PbO, V2O5, Fe2O3, P2O5, B2O3, SiO2, etc. However, the present invention is not limited thereto, and if a source for melting the bonding member 300 is modified, the bonding member 300 may use a UV curing material, a thermal curing material, etc.

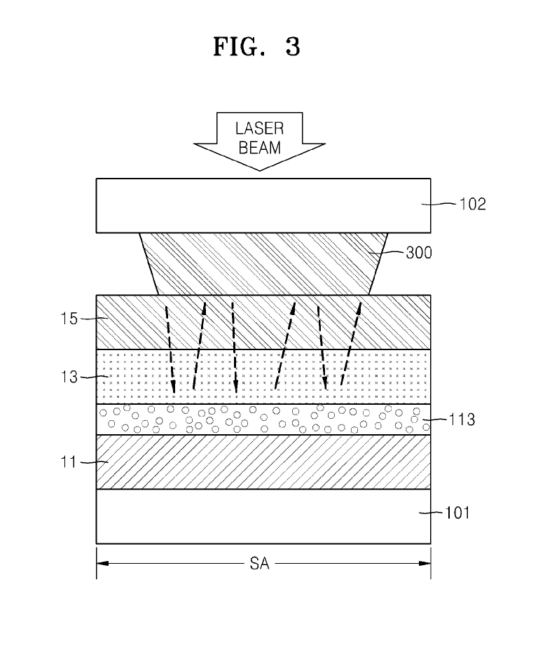

The bonding region SA of FIG. 1 is described in detail below with reference to FIGS. 3 through 6.

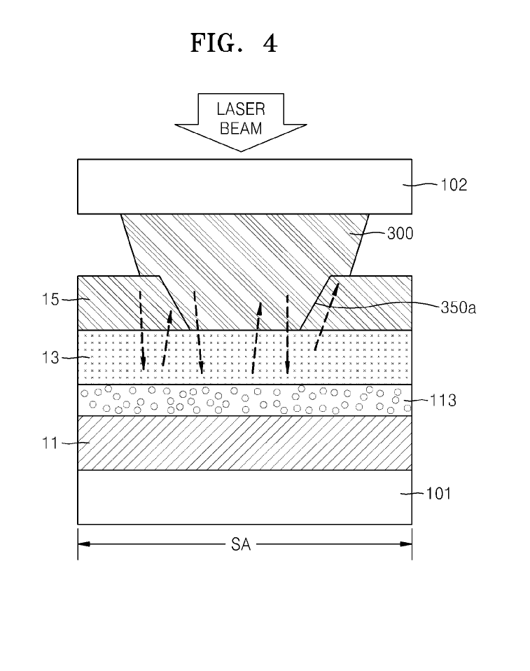

FIG. 3 is a cross-sectional view of the bonding region SA of FIG. 1 according to an embodiment of the present invention. FIGS. 4 through 6 are cross-sectional views of the bonding region SA of FIG. 1 according to other embodiments of the present invention.

Referring to FIG. 3, the buffer layer 11, the semiconductor layer 113, the gate insulation layer 13, and the interlayer insulation layer 15 are sequentially formed in the bonding region SA partitioned in the first substrate 101. The bonding member 300 is disposed on the interlayer insulation layer 15. The second substrate 102 is disposed on the bonding member 300.

As described above, the semiconductor layer 113 reflects, diffracts, and scatters a laser beam incident through the bonding member 300 and irradiates the laser beam onto the bonding member 300, thereby increasing an effective bonding width of the bonding member 300, increasing mechanical strength, and improving interfacing characteristics between a lower substrate and the bonding member 300.

Referring to FIG. 4, unlike FIG. 3, a concave portion 350a is formed in the interlayer insulation layer 15 formed in the bonding region SA. The bonding member 300 is buried in the concave portion 350a so that a bottom surface of the bonding member 300 contacts a top surface of the gate insulation layer 13. In embodiments, a width of the concave portion 350a is smaller than that of the bonding member 300.

In the present embodiment, a gap between the bonding member 300 and the semiconductor layer 113 is reduced. Thus, the amount of heat that is inversely transferred to the bonding member 300 from the semiconductor layer 113 increases, when compared to FIG. 3. Furthermore, the bonding member 300 is buried in the concave portion 350a, and the width of the concave portion 350a is smaller than that of the bonding member 300, and thus an area where the bonding member 300 and the lower substrate are bonded to each other is large, when compared to FIG. 3. Such an increase in the contact area enables a firmer bonding, which improves mechanical strength. Finally, when the bonding member 300 used in FIG. 3 is applied in FIG. 4 without a modification of the bonding member 300, a gap between the second substrate 102 and the lower substrate is reduced by a height of the concave portion 350a, and thus it is possible to reduce the phenomenon of Newton's rings caused by a relatively large gap between two substrates.

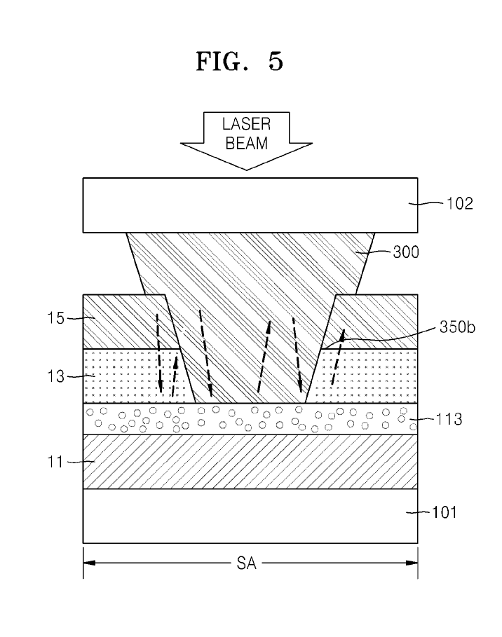

Referring to FIG. 5, a concave portion 350b is formed in a lower substrate, like FIG. 4. However, unlike FIG. 4, the concave portion 350b is formed in the interlayer insulation layer 15 and the gate insulation layer 13 that are formed in the bonding region SA. The bonding member 300 is buried in the concave portion 350b so that a bottom surface of the bonding member 300 contacts a top surface of the semiconductor layer 113. In embodiments, a width of the concave portion 350b is smaller than that of the bonding member 300.

In the present embodiment, the concave portion 350b is formed in the gate insulation layer 13, which forms a portion where the bonding member 300 and the semiconductor layer 113 directly contact each other. Thus, an amount of heat that is inversely transferred from the semiconductor layer 113 to the bonding member 300 increases. The semiconductor layer 113 may absorb the amount of heat. The amount of heat absorbed by the semiconductor layer 113 improves the interfacing characteristics between the bonding member 300 and the semiconductor layer 113, which increase an effective bonding area. In addition, the bonding member 300 is buried in the concave portion 350b, and a width of the concave portion 350b is smaller than that of the bonding member 300, and thus an area where the bonding member 300 and the lower substrate are bonded to each other is large. Furthermore, a gap between the second substrate 102 and the lower substrate is reduced, compared to FIG. 4, by a height of the concave portion 350b formed in the gate insulation layer 13, and thus it is possible to reduce the phenomenon of Newton's rings caused by a relatively large gap between two substrates.

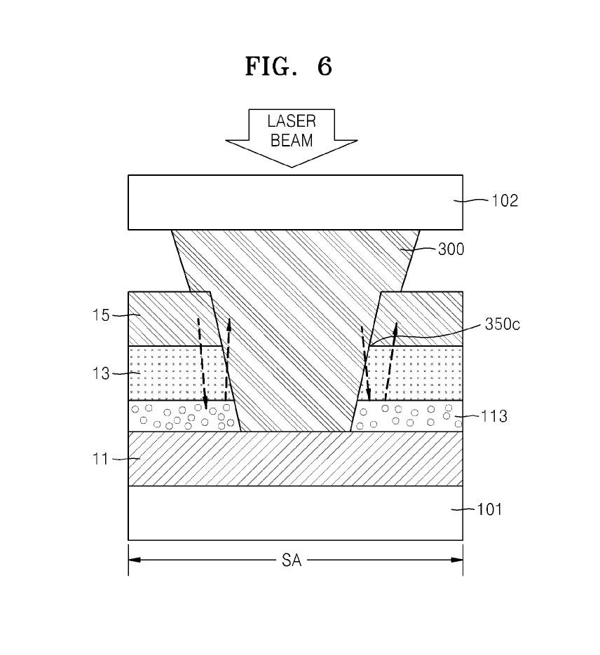

Referring to FIG. 6, a concave portion 350c is formed in a lower substrate, like in FIGS. 4 and 5. However, unlike in FIG. 5, the concave portion 350c is formed in the interlayer insulation layer 15, the gate insulation layer 13, and the semiconductor layer 113, which are formed in the bonding region SA. The bonding member 300 is buried in the concave portion 350c so that a bottom surface of the bonding member 300 contacts a top surface of the buffer layer 11. In embodiments, a width of the concave portion 350c is smaller than that of the bonding member 300.

In the present embodiment, the concave portion 350b is formed in the semiconductor layer 113, so that a circumference of the bonding member 300 and the semiconductor layer 113 directly contact each other, which maximizes a contact area between the semiconductor layer 113 and the bonding member 300. Thus, an amount of heat that is inversely transferred from the semiconductor layer 113 to the bonding member 300 increases. An amount of heat absorbed by the semiconductor layer 113 improves the interfacing characteristics between the bonding member 300 and the semiconductor layer 113, which increase an effective bonding area. In particular, when the semiconductor layer 113 is doped with impurities, heat absorption of the semiconductor layer 113 can be controlled by adjusting an energy band gap of the semiconductor layer 113, thereby controlling an effective bonding area. In addition, the bonding member 300 is buried in the concave portion 350c, and a width of the concave portion 350c is smaller than that of the bonding member 300, and thus an area where the bonding member 300 and the lower substrate are bonded to each other is large. Furthermore, a gap between the second substrate 102 and the lower substrate is reduced by a height of the concave portion 350c formed in the semiconductor layer 113, compared to FIG. 5, and thus it is possible to reduce the phenomenon of Newton's rings caused by a relatively large gap between two substrates.

According to embodiments of the present invention, the semiconductor layer 113 and the concave portions 350a, 350b, and 350c result in an increase in an effective bonding area of the bonding member 300. As a test result, when the effective bonding area of the bonding member 300 increases, the results of a pulling test and a 4 point bending test are improved. Furthermore, as the gap between the second substrate 102 and the lower substrate decreases, the defects of the Newton's rings decrease. As discussed above, the concave portions 350a, 350b, and 350c reduce the gap between the second substrate 102 and the lower substrate, thereby enabling the manufacture of a highly reliable apparatus.

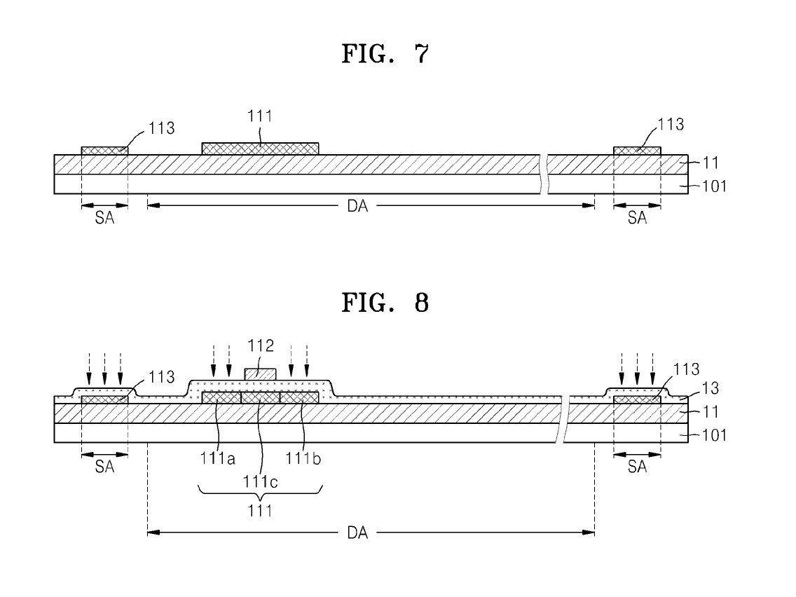

FIGS. 7 through 10 are diagrams for explaining a method of manufacturing the organic light emitting display apparatus of FIG. 1 according to embodiments of the present invention.

Referring to FIG. 7, the buffer layer 11 is formed on the first substrate 101 including the display region DA and the bonding region SA. Thereafter, the semiconductor layer 113 including polycrystalline polysilicon is formed on the bonding region SA of the first substrate 101 in a closed loop so as to surround the display region DA. Simultaneously, the active layer 111 is formed on the display region DA of the first substrate, and is formed of the same material as the semiconductor layer 113.

Referring to FIG. 8, the gate insulation layer 13 is wholly formed on the semiconductor layer 113 and the active layer 111 of FIG. 7, and the gate electrode 112 is formed in a region corresponding to the active layer 111. The source region 111a and the drain region 111b of the semiconductor layer 113 and the active layer 11 are doped with impurities. In this regard, the source region 111a and the drain region 111b are doped with boron or phosphorus ions. Meanwhile, although the semiconductor layer 113 is doped with impurities in FIG. 8, the present invention is not limited thereto, and the semiconductor layer 113 may not be doped with impurities.

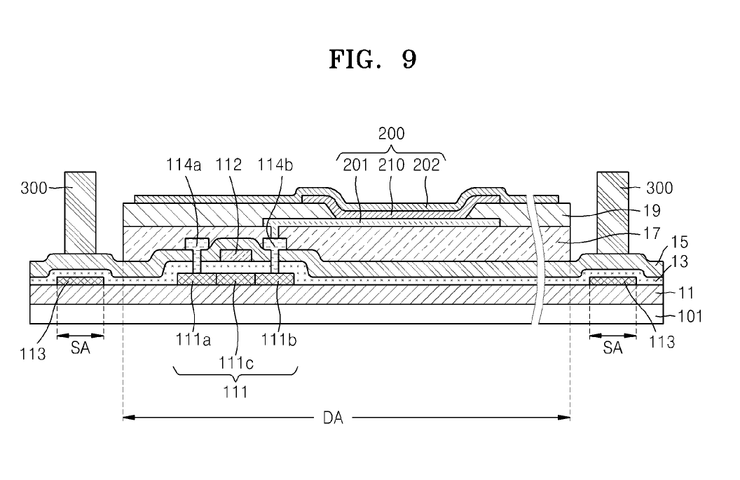

Referring to FIG. 9, the interlayer insulation layer 15 is wholly formed on the gate electrode 112 of FIG. 8, the source and drain electrodes 114a and 114b are formed in the display region DA, the planarization layer 17 is formed, and the organic light emitting device 200 including the pixel electrode 201, the light emitting member 210, and the facing electrode 202 is formed. The pixel definition layer 19 is formed to define a plurality of pixels. In this regard, the bonding member 300 is disposed on the interlayer insulation layer 15 in the bonding region SA.

In the present embodiment, the concave portions 350a, 350b, and 350c may be formed in one or more layers of the gate insulation layer 13, the interlayer insulation layer 15, and the semiconductor layer 113, which correspond to the bonding region 300 before the bonding member 300 is disposed. In this case, the bonding member 300 is formed to be buried in the concave portions 350a, 350b, and 350c. The shapes and functions of the concave portions 350a, 350b, and 350c are described in detail with reference to FIGS. 4 through 6, and thus redundant descriptions thereof are not repeated.

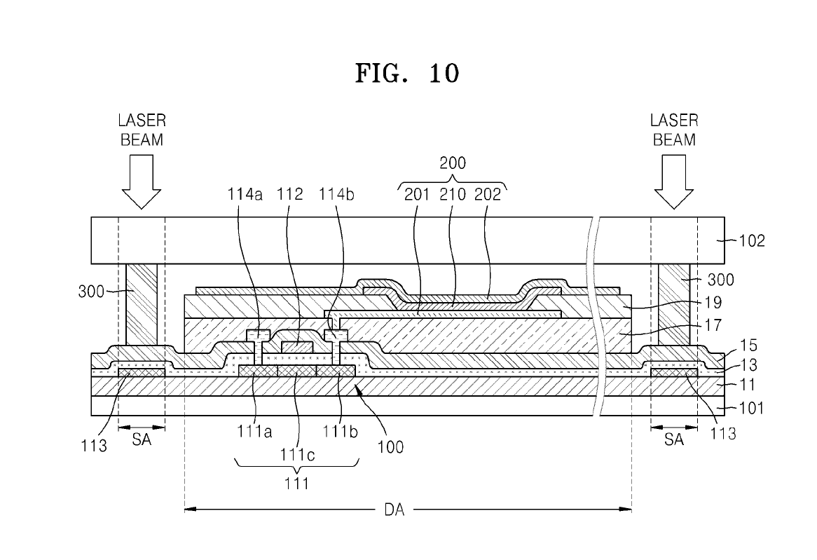

Referring to FIG. 10, the second substrate 102 is disposed on the bonding member 300 of FIG. 9, the bonding member 300 is melted and cured by irradiating laser beam onto a region corresponding to the bonding region SA in another surface of the second substrate 102, and the display region DA of the first substrate 101 is encapsulated.

Although an organic light emitting device is described in the present description, a flat display apparatus including a liquid crystal display apparatus, a plasma display apparatus, etc. that encapsulates an upper substrate and a lower substrate by using an encapsulation member may be applied to embodiments of the present invention.

As described above, according to embodiments of the present invention, a semiconductor layer formed in a bonding region of a lower substrate reflects, scatters, and refracts a laser beam used to melt a bonding member and increases a bonding area between the bonding member, the lower substrate, and an encapsulation substrate, thereby improving interfacing characteristics between the lower substrate and the bonding member and between the encapsulation substrate and the bonding member, increasing mechanical strength, and reducing defectiveness.

Further, a bonding member is buried in a concave portion formed in a bonding region of a lower substrate, thereby increasing a contact area between the bonding member and the lower substrate, reducing a gap between the lower substrate and an encapsulation substrate, and improving mechanical strength.

While the present invention has been particularly shown and described with reference to embodiments thereof, it will be understood by those of ordinary skill in the art that various changes in form and details may be made therein without departing from the spirit and scope of the present invention as defined by the following claims.

1. An organic light emitting display apparatus comprising:
a first substrate comprising a display region disposed in a center of one surface thereof and a bonding region formed along a closed loop to surround the display region;
a semiconductor layer corresponding to the bonding region of the first substrate, formed along the closed loop to surround the display region, and comprising a polycrystal;
at least one insulation layer formed over the semiconductor layer;
a bonding member formed over the at least one insulation layer and formed in a region corresponding to the semiconductor layer; and
a second substrate comprising one surface disposed to face the surface of the first substrate and coupled to the bonding member to encapsulate the display region of the first substrate.

2. The apparatus of claim 1, wherein the semiconductor layer comprises polycrystalline polysilicon.

3. The apparatus of claim 1, wherein the semiconductor layer comprises polycrystalline polysilicon doped with impurities.

4. The apparatus of claim 1, further comprising a thin film transistor (TFT) comprising:
an active layer formed in the display region of the first substrate;
a gate insulation layer formed over the active layer;
a gate electrode formed over the gate insulation layer and insulated from the active layer;
an interlayer insulation layer formed over the gate electrode; and
source and drain electrodes formed over the interlayer insulation layer and contacting the active layer.

5. The apparatus of claim 4, wherein the thin film transistor comprises the active layer formed simultaneously with formation of the semiconductor layer on a layer on which the semiconductor layer is formed.

6. The apparatus of claim 4, wherein the insulation layer comprises the gate insulation layer and the interlayer insulation layer.

7. The apparatus of claim 1, wherein the insulation layer comprises a gate insulation layer and an interlayer insulation layer, and
wherein a concave portion is formed in a region of the interlayer insulation layer corresponding to the bonding region, and a portion of the bonding member is received in the concave portion and contacts the gate insulation layer.

8. The apparatus of claim 1, wherein the insulation layer comprises a gate insulation layer and an interlayer insulation layer, and
wherein a concave portion is formed in the interlayer insulation layer and the gate insulation layer at a region which corresponds to the bonding region, and a portion of the bonding member is received in the concave portion and contacts the semiconductor layer.

9. The apparatus of claim 1, wherein the insulation layer comprises a gate insulation layer and an interlayer insulation layer, and
wherein a concave portion is formed in the interlayer insulation layer, the gate insulation layer, and the semiconductor layer at a region which corresponds to the bonding region, and a portion of the bonding member is received in the concave portion.

10. The apparatus of claim 7, wherein a width of the concave portion is smaller than that of the bonding member.

11. The apparatus of claim 1, further comprising: a buffer layer formed over the entire portion of the surface of the first substrate.

12. A method of manufacturing an organic light emitting display apparatus, the method comprising:
providing a first substrate comprising a display region disposed in a center of one surface thereof and a bonding region formed along a closed loop to surround the display region;
forming a semiconductor layer corresponding to the bonding region of the first substrate, wherein the semiconductor layer is formed along the closed loop to surround the display region, and comprising a polycrystal;
forming at least one insulation layer over the semiconductor layer;
forming a bonding member over the at least one insulation layer and formed in a region corresponding to the semiconductor layer; and
disposing a second substrate comprising one surface to face the surface of the first substrate; and
applying laser to a region corresponding to the bonding region through the second substrate, thereby melting the bonding member and encapsulating the display region.

13. The method of claim 12, wherein the semiconductor layer comprises polycrystalline polysilicon,
the method further comprising doping the semiconductor layer with impurities.

14. The method of claim 12, further comprising:
forming an active layer in the display region of the first substrate;
forming a gate insulation layer over the active layer;
forming a gate electrode insulated from the active layer over the gate insulation layer;
forming an interlayer insulation layer over the gate electrode; and
forming source and drain electrodes over the interlayer insulation layer and contacting the active layer.

15. The method of claim 14, wherein the semiconductor layer is formed simultaneously with the formation of the active layer.

16. The method of claim 14, wherein the insulation layer comprises the gate insulation layer and the interlayer insulation layer.

17. The method of claim 12, wherein the insulation layer comprises a gate insulation layer and an interlayer insulation layer,
the method further comprising, before forming the bonding member, forming a concave portion in a region of the interlayer insulation layer corresponding to the bonding region,
wherein the bonding member is received in the concave portion and contacts the gate insulation layer.

18. The method of claim 12, wherein the insulation layer comprises the gate insulation layer and the interlayer insulation layer,
the method further comprising, before forming the bonding member, forming a concave portion in the interlayer insulation layer and the gate insulation layer at a region which corresponds to the bonding region,
wherein a portion of the bonding member is received in the concave portion and contacts the semiconductor layer.

19. The method of claim 12, wherein the insulation layer comprises a gate insulation layer and an interlayer insulation layer,
the method further comprising, before forming the bonding member, forming a concave portion is formed in the interlayer insulation layer, the gate insulation layer, and the semiconductor layer at a region which corresponds to the bonding region,
wherein a portion of the bonding member is received in the concave portion.

20. The method of claim 12, further comprising forming a buffer layer over the entire portion of the surface of the first substrate.
